(19) United States
(12) Patent Application Publication
(10) Pub. No.: US 2012/0313149 A1
(43) Pub. Date: Dec. 13, 2012

(54) SEMICONDUCTOR STRUCTURE AND METHOD FOR MANUFACTURING THE SAME

(75) Inventors: Haizhou Yin, Poughkeepsie, NY (US); Huilong Zhu, Poughkeepsie, NY (US); Zhijiong Luo, Poughkeepsie, NY (US)

(73) Assignees: BEIJING NMC CO., LTD., Beijing (CN); Institute, of Microelectronics, Chinese Academy of Sciences, Beijing (CN)

(21) Appl. No.: 13/380,707

(22) PCT Filed: Aug. 25, 2011
(86) PCT No.: PCT/CN2011/078891

§ 371 Date: Dec. 23, 2011

(30) Foreign Application Priority Data
Jun. 9, 2011 (CN) 201110154452.1

(51) Int. Cl. H01L 29/78; H01L 21/336

(52) U.S. Cl. 257/288; 438/299; 257/E29.255; 257/E21.409

(57) ABSTRACT

The present invention provides a semiconductor structure and a method for manufacturing the same. The method comprises the following steps: providing a semiconductor substrate, forming sequentially a gate dielectric layer, a metal gate, a CMP stop layer, and a poly silicon layer on the semiconductor substrate; etching the gate dielectric layer, the metal gate, the CMP stop layer and the poly silicon layer to form a gate stack; forming a first interlayer dielectric layer on the semiconductor substrate to cover the gate stack on the semiconductor substrate and the portions on both sides of the gate stack; performing a planarization process, such that the CMP stop layer is exposed and flushed with the upper surface of the first interlayer dielectric layer. Accordingly, the present invention further provides a semiconductor structure. Through adding the CMP stop layer, the present invention is able to effectively shorten the height of a metal gate, thus effectively reduces the capacitance between the metal gate and contact regions, and therefore optimizes the subsequent process for etching through holes.

The present application claims priority benefit of Chinese Patent Application No. 201110154452.1 titled “Semiconductor Structure and Method for Manufacturing the Same” filed on 9 Jun. 2011, which is herein incorporated by reference in its entirety.

### FIELD OF THE INVENTION

The present invention relates to semiconductor manufacturing, and specifically relates to a semiconductor structure and its manufacturing method.

### BACKGROUND OF THE INVENTION

As the semiconductor industry develops, integrated circuits with better performance and more powerful functions require greater component density. Moreover, the size of and the space between the components become further scaled down (has already reached 45 nm or less at present time). Thus, requirements of process control during manufacturing a semiconductor device become increasingly stringent.

The height of a gate stack affects the parasitic capacitance between the gate and source/drain (S/D) contact structures and their electrical extensions (e.g. extension doping overlapped with the gate and metalized contacts). The capacitance between the gate and source/drain extensions not only affects the current drive capability and power consumption, but also affects significantly the overall speed of the integrated circuit operated in logic architectures. Therefore, it is desirable to shorten the height of a gate.

The traditional CMOS process limits the room for shortening the gate height. Due to decrease in the gate height, the dopants, which are implanted to dope source/drain regions with sufficient energy, might penetrate into the channel through the gate stack and gate dielectric. Therefore, along with decrease in the gate height, the lower layer of gate oxide is more probably polluted by gate dopants. In order to eliminate such risk, some traditional processes propose to reduce the entire thermal budget of the manufacturing procedure. However, because of reduction of the thermal budget, the dopants in other electrodes may not be sufficiently activated, which might consequently curb the drive current. Alternatively, the penetration of dopants may be alleviated by way of significantly lowering the implantation energy for self-aligned source/drain and Halo. However, the lowered implantation energy for the self-aligned source/drain and Halo would cause a high source/drain parasitic capacitance, which makes the Halo inside the channel not doped sufficiently, reduces the drive current and even impairs the short channel roll-off characteristics.

Conversely, when traditional MOS process of Raised Source/Drain (RSD) is applied to reduce the relative gate height, it would be affected by the unnecessarily Temporary Enhanced Diffusion (TED). Namely, during the RSD process, the impurities such as Boron might diffuse into the channel arising from Halo implantation for N-type Field Effect Transistors (NFET) and extension implantation and source/drain implantation for P-type Field Effect Transistors (PFET). Specifically, the extended thermal cycling for Si selective epitaxial growth is performed at a temperature about 700° C.˜900° C. for a few minutes so as to grow RSD on a thin SOI (silicon-on-insulator) structure. It is generally well known that such a thermal condition would cause the most significant TED of main dopants (esp. Boron), which is harmful to devices with short channels, for example, increasing the roll-off rate of threshold voltages.

Therefore, it is urgent to propose a semiconductor structure and its manufacturing method, which is able to lower the gate height but does not impair the performance thereof.

### SUMMARY OF THE INVENTION

The present invention aims to provide a semiconductor structure and its manufacturing method, which is favorable for effectively reducing the gate height, thereby reducing capacitance between the metal gate and contact regions, and lowering the requirement for process preciseness and difficulty to etch through holes.

According to an embodiment of the present invention, the present invention provides a method for manufacturing a semiconductor structure, which comprises following steps:

(a) providing a semiconductor substrate and sequentially forming a gate dielectric layer, a metal gate, a CMP (Chemical Mechanical Polishing) stop layer, and a poly silicon layer on the semiconductor substrate;

(b) etching the gate dielectric layer, the metal gate, the CMP stop layer, and the poly silicon layer to form a gate stack;

(c) forming a first interlayer dielectric layer on the semiconductor substrate to cover the gate stack on the semiconductor substrate and the portions on both sides of the gate stack;

(d) performing a planarization process such that the CMP stop layer is exposed and flushed with the upper surface of the first interlayer dielectric layer.

Accordingly, in an embodiment of the present invention, the present invention provides a semiconductor structure, comprising a substrate, a gate stack, a first interlayer dielectric layer, and source/drain regions, wherein: the source/drain regions are embedded within the substrates, the gate stack is formed on the substrate, and the first interlayer dielectric layer covers the source/drain regions; and

wherein,

the gate stack sequentially comprises: a gate dielectric layer in contact with the substrate, a metal gate, and a CMP stop layer.

As compared to the prior art, the semiconductor structure and its manufacturing method provided by the present invention exhibit the following advantages:

At formation of a gate stack, a CMP stop layer is applied such that the poly silicon layer may be removed at the time of performing planarization process, which accordingly is stopped at the CMP stop layer. Usually, the planarization process is stopped at a poly silicon layer, whereas the present invention proposes to introduce a CMP stop layer, whose hardness is greater than that of a poly silicon layer, such that the poly silicon layer may be removed at the time of performing the planarization process and thus the gate height shall be effectively shortened. In the conventional process, it is impossible to fabricate a very thin gate stack mainly because when source and drain are implanted with ions, the gate would be easily penetrated through, if the gate has been made very thin. However, after formation of the source and drain, a planarization process is performed till the poly silicon layer is removed, such that the CMP stop layer added by the present invention is exposed, thus the gate height is effectively shortened. Meanwhile, owing to the decrease in the gate height, the capacitance between the gate and the contact regions would be reduced. Additionally, because the difference of heights between the gate and source/drain becomes smaller, the distance to be etched become shorter at the time of etching through holes. Therefore, compared to the traditional process for etching through holes, it becomes easier to control the etching distance and accuracy, which therefore optimizes the process of etching through holes.

### BRIEF DESCRIPTION OF THE DRAWINGS

Other characteristics, objectives and advantages of the present invention are made more evident according to the following detailed description of exemplary embodiment(s) in conjunction with accompanying drawings.

FIG. 1 illustrates a flowchart of a method for manufacturing a semiconductor structure according to an embodiment of the present invention;

FIGS. 2-12 illustrate cross-sectional structural diagrams of a semiconductor structure at respective manufacturing stages.

Same or similar reference signs in the accompanying drawings denote same or similar elements.

### DETAILED DESCRIPTION OF THE INVENTION

Objectives, technical solutions, and advantages of the present invention are made more evident according to the following detailed description of exemplary embodiments in conjunction with the accompanying drawings.

Embodiments of the present invention are described here below, wherein the examples of the embodiments are illustrated in the drawings, in which same or similar reference signs throughout denote same or similar elements or elements have same or similar functions. It should be appreciated that the embodiments described below in conjunction with the drawings are illustrative and are provided for explaining the present invention only. Thus, they shall not be interpreted as a limit to the present invention.

Various embodiments or examples are provided here below to implement different structures of the present invention. To simplify the disclosure of the present invention, description of the components and arrangements of specific examples is given below. Of course, they are illustrative only and not limiting the present invention. Moreover, in the present invention, reference numbers and/or letters may be repeated in different embodiments. Such repetition is for the purpose of simplification and clearness. It does not denote the relationship between respective embodiments and/or arrangements being discussed. Furthermore, the present invention provides various examples for various process and materials. However, it is obvious to a person of ordinary skill in the art that other processes and/or materials may alternatively be utilized. In addition, the following structure in which a first feature is “on/above” a second feature may include an embodiment in which the first feature and the second feature are formed to be in direct contact with each other, and may also include an embodiment in which another feature is formed between the first feature and the second feature, such that the first and second features might not be in direct contact with each other. It should be noted that, the elements shown in the drawings might not be drawn to scale. The description of the conventional components, processing technologies, and crafts are omitted herein in order not to unnecessarily limit the present invention.

A semiconductor structure provided by the present invention is described below.

With reference to FIG. 5, which illustrates a cross-sectional structural diagram of a semiconductor structure provided by the present invention, the semiconductor structure comprises a substrate 100, a gate stack, a first interlayer dielectric layer 115, source/drain regions 101, wherein: the source/drain regions 101 are embedded within the substrate 100, the gate stack is formed on the substrate 100 and the first interlayer dielectric layer 115 covers the source/drain regions 101; the gate stack comprises sequentially: a gate dielectric layer 111 in contact with the substrate 100, a metal gate 112 and a CMP stop layer 113.

Preferably, the top surface of the gate stack is flushed with the upper plane of the first interlayer dielectric layer 115 (herein, the term “flushed with” indicates that the difference between the heights of the two is in the range of permitted technical error).

A total thickness of the metal gate 112 and the CMP stop layer 113 may be about 20 nm Preferably, the thickness of the metal gate 112 may be about 5 nm and the thickness of the CMP stop layer 113 may be about 15 nm

In the following, aforesaid semiconductor structure and its possible variation(s) are further described in view of a method for manufacturing a semiconductor device provided by the present invention.

With reference to FIG. 1, which illustrates a flowchart of a method for manufacturing a semiconductor structure according to an embodiment, the method comprises:

at step S101, providing a semiconductor substrate 100, forming sequentially a gate dielectric layer 111, a metal gate 112, a CMP stop layer 113 and a poly silicon layer 114 on the substrate 100;

at step S102, etching the gate dielectric layer 111, the metal gate 112, the CMP stop layer 113 and the poly silicon layer 114 to form a gate stack;

at step S103, forming a first interlayer dielectric layer 115 on the semiconductor substrate 100 to cover the gate stack on the semiconductor substrate 100 and the portions on both sides of the gate stack;

at step S104, performing a planarization process, such that the CMP stop layer 113 is exposed and flushed with the upper surface of the first interlayer dielectric layer 115 (herein, the term “flushed with” indicates that the difference between the heights of the two is in the range of permitted technical error).

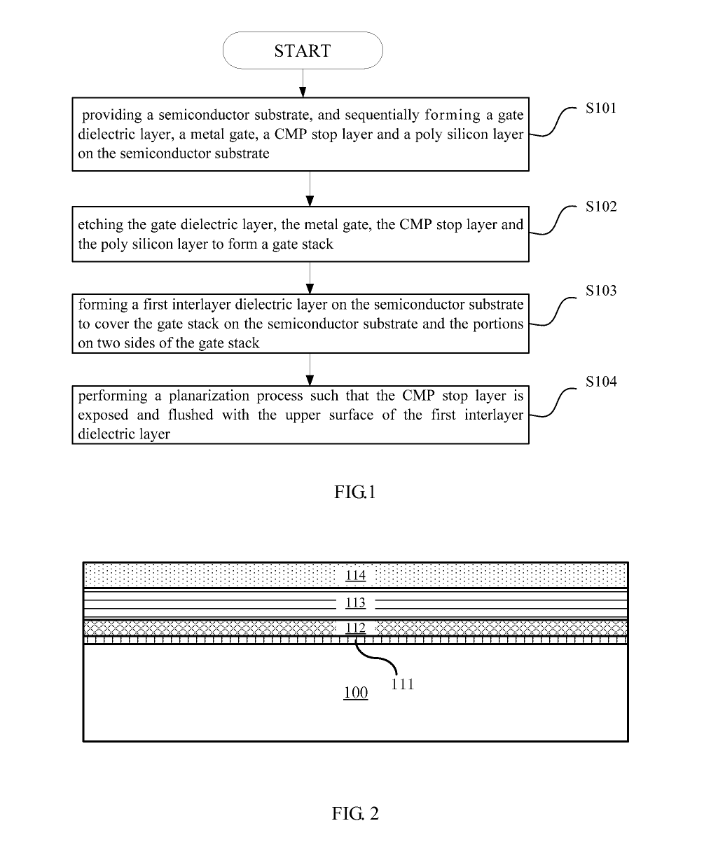

Step S101 through step S104 are described below in conjunction with FIGS. 2-12, which illustrate cross-sectional structural diagrams of a semiconductor structure at respective manufacturing stages of the method according to the embodiment of the present invention as shown in FIG. 1. It should be noted that the drawings for respective embodiments are illustrative only, thus are not necessarily drawn to scale.

A semiconductor substrate 100 is provided at step S101. With reference to FIG. 2, the substrate 100 includes a silicon substrate (e.g. silicon wafer). According to the design requirement in the prior art (e.g. a P-type substrate or an N-type substrate), the substrate 100 may be of various doping configurations. The substrate 100 in other embodiments may further include other basic semiconductor, for example germanium. Alternatively, the substrate 100 may include a compound semiconductor, such as SiC, GaAs, InAs or InP. Typically, the substrate 100 may have but not limited to a thickness of several hundred micrometers. For instance, it could fall in the range between 400 micrometers and 800 micrometers.

A gate dielectric layer 111 is deposited on the semiconductor substrate 100. The gate dielectric layer 111, which is located on the semiconductor substrate 100, could be a thermal oxide layer, including SiO₂ or Si₂N₂O, or could be a high-k dielectric, for example, one of HfAlON, HfSiAlON, HfTaAlON, HfTiAlON, HfON, HfSiON, HfTaON and HfTiON, or any combination thereof The thickness of the gate dielectric layer 111 may be between 2 nm and 10 nm, for example, 2 nm, 5 nm, or 8 nm.

A metal gate 112 is deposited on the gate dielectric layer 111 by way of, for example, depositing one of TaN, TaC, TiN, TaAlN, TiAlN, MoAlN, TaTbN, TaErN, TaYbN, TaSiN, HfSiN, MoSiN, RuTax, and NiTax, or any combination thereof.

A CMP stop layer 113 is formed on the metal gate 112. The CMP stop layer (113) may be formed from a rigid metal material or a compound, whose hardness coefficient is greater than that of the poly silicon layer (114). For example, the material for the CMP stop layer (113) includes but not limited to one of Ni, Ti, Cr, Pt, and TiN, or any combination thereof Usually, the Mohs' scale of hardness of poly silicon is 4.5-6.5, thus the CMP stop layer (113) is made of, for example, a rigid metal with Mohs' scale of hardness greater than 6.5, namely, the hardness of the metal is greater than that of the poly silicon material.

A total thickness of the metal gate 112 and the CMP stop layer 113 may be about 20 nm. Preferably, the thickness of the metal gate may be about 5 nm, while the thickness of the CMP stop layer 113 may be about 15 nm.

A poly silicon layer 114 is formed on the CMP stop layer 113. The formation of the poly silicon layer 114 may be according to the following steps: first, forming an amorphous silicon layer on the CMP stop layer 113; second, irradiating the amorphous silicon layer with an excimer laser beam to transform the amorphous silicon into a melting state; finally, cooling and re-crystallizing the amorphous silicon into poly silicon, i.e., to form the poly silicon layer 114. It should be noted that, there are plenty of methods for forming the poly silicon layer 114, and persons of ordinary skill in the art know them very well. Thus, these methods are not described specifically here. The abovementioned method is exemplary only and not to be interpreted as a limitation to the present invention.

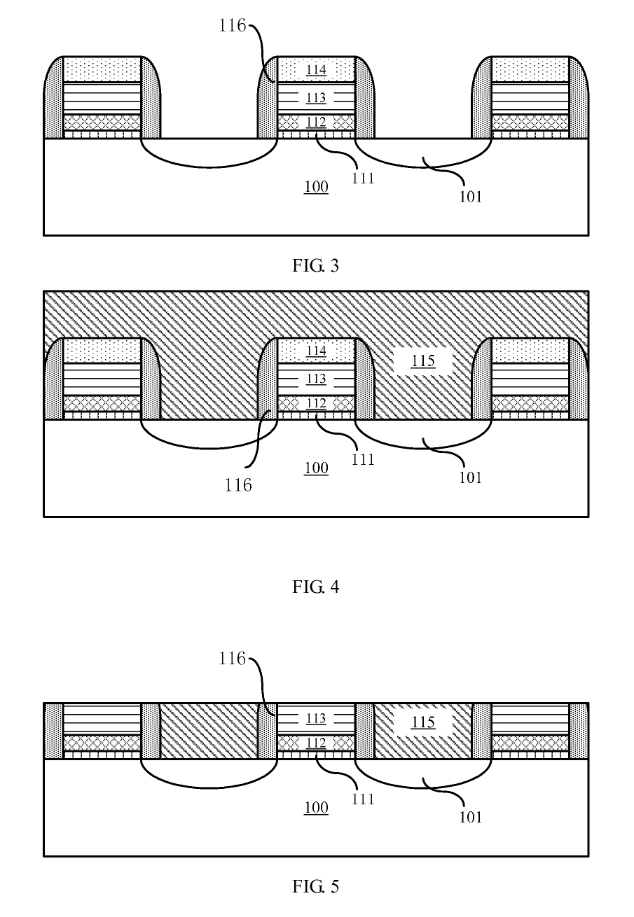

A gate stack and source/drain regions 101 are formed at step S102, as shown in FIG. 3. The multi-layer structure formed at step S101 is overlaid with photo resist and then is patterned. The gate dielectric layer 111, the metal gate 112, the CMP stop layer 113 and the poly silicon layer 114 are etched, which is stopped on the semiconductor substrate 100, so as to form a gate stack.

Optionally, sidewall spacers 116 are formed on sidewalls of the gate stack for isolating the gate stack. The sidewall spacers 116 may be formed from Si₃N₄, SiO₂, Si₂N₂O, SiC, or their combination, and/or other material as appropriate. The sidewall spacers 116 may be in a multi-layer structure. The sidewall spacers 116 are formed by means of deposition and etching process and its thickness may be in the range between nm and 100 nm, for example 30 nm, 50 nm or 80 nm.

Optionally, source/drain regions 101 are formed on both sides of the gate stack. The source/drain regions 101 may be formed through implanting P-type or N-type dopants or impurities into the substrate 100. For example, for PMOS, the source/drain regions 101 may be P-type doped SiGe; for NMOS, the source/drain regions 110 may be N-type doped Si. The source/drain regions 101 may be formed by way of lithography, ion implantation, diffusion, epitaxial growth and/or any other method as appropriate, and may be formed prior to the gate dielectric layer 111. In the present embodiment, the source/drain regions 101 are located within the substrate 100, while in other embodiments, the source/drain regions 101 may be raised source/drain structures formed by means of selective epitaxial growth, wherein the top surfaces of the epitaxial portions are higher than the bottom of the gate stack (herein, the bottom of the gate indicates the boundary of the gate stack and the semiconductor substrate 100).

At step S103, a first interlayer dielectric layer 115 is formed on the semiconductor substrate 100 to cover the source/drain regions 101 and the gate stack located on the semiconductor substrate 100. As shown in FIG. 4, the space around the gate stack is also filled with the first interlayer dielectric layer 115.

The first interlayer dielectric layer 115 may be formed on the substrate 100 by means of Chemical Vapor Deposition (CVD), High-Density Plasma CVD, spin coating, or other method as appropriate. The materials for the first interlayer dielectric layer 115 may include SiO₂, carbon-doped SiO₂, BPSG, PSG, UGS, Si₂N₂O, a low-k material, or their combination. The thickness of the first interlayer dielectric layer 115 may be in the range between 40 nm to 150 nm, for example, 80 nm, 100 nm or 120 nm.

A planarization process is performed at step S104, such that the CMP stop layer 113 is exposed and became level with the upper surface of the first interlayer dielectric layer 115.

In the present embodiment, a planarization process is performed to the first interlayer dielectric layer 115 and the gate stack on the semiconductor device by means of Chemical-Mechanical Polish (CMP), such that the upper surface of the CMP stop layer 113 within the gate stack is flushed with the upper surface of the first interlayer dielectric layer 115, and the top surface of the CMP stop layer 113 and sidewall spacers 116 are exposed at the meantime, as shown in FIG. 5. The present invention innovatively introduces the use of a CMP stop layer 113, since the CMP stop layer 113 is formed with a metal of a high hardness coefficient, thus it may function as a stop layer for the planarization process instead of a poly silicon layer in traditional processes. Namely, when the planarization process is performed, the poly silicon layer 114 located above the stop layer is removed, therefore the gate height is effectively shortened.

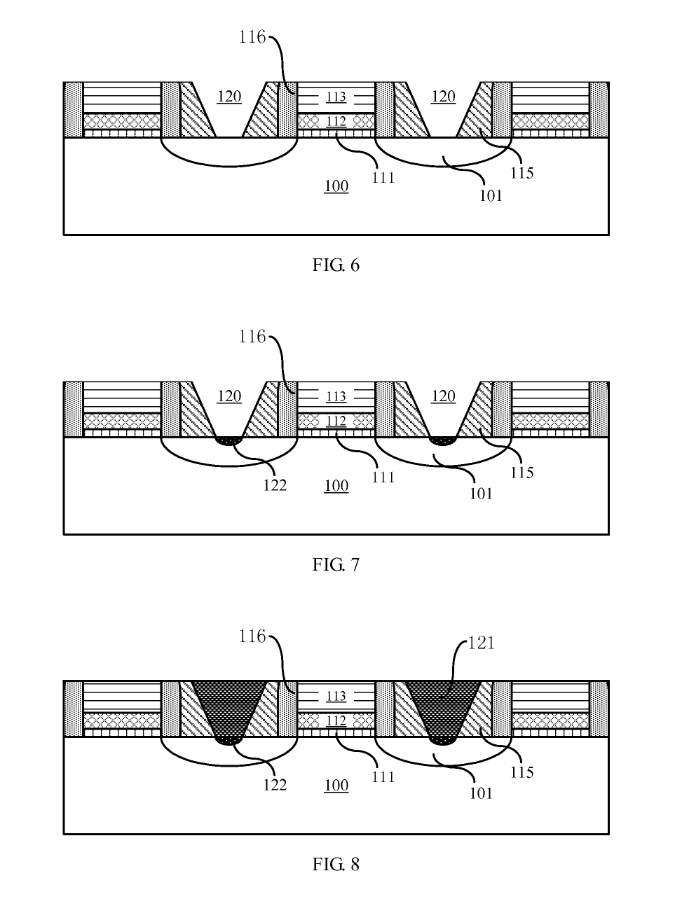

Optionally, contact vias 121 may be further formed, as shown in FIGS. 6-12.

As shown in FIG. 6, the first interlayer dielectric layer 115 is etched to form through holes 120 that at least partially expose the source/drain regions 101 on the substrate. Specifically, the through holes 120 may be formed through etching the first interlayer dielectric layer 115 by means of dry etching, wet etching or other etching method as appropriate. The source/drain regions 101 within the substrate 100 are exposed after formation of the through holes 120. Because the gate stack has been protected by the sidewall spacers 116, thus even if over-etching happens during formation of the through holes 120, no short circuit shall arise between the gate and the source/drain. In case the source/drain regions 101 are raised source/drain structures formed by means of selective epitaxial growth, and the top surfaces of the epitaxial portions are higher than the bottom of the gate stack, then the through holes 120 may be formed as deep as reaching the locations inside the source/drain regions 101 that are at the same level as the bottom of the gate stack. In this way, when contact vias 121 are formed through filling the through holes 120 with a contact metal, the contact metal shall be in contact with the source/drain regions 101 at the bottom and a portion of the sidewalls of the through holes 120, which therefore further increases the contact area yet reduces the contact resistance.

As shown in FIG. 7, the exposed source/drain regions 101 are located at the bottoms of the through holes 120. A metal is deposited on the source/drain regions 101 and then annealed to form metal silicide 122. Specifically, a pre-amorphization treatment is performed to the exposed source/drain regions 101 by way of implanting ions, depositing an amorphous compound or selective growing through the through holes 120, so as to form partial amorphous silicon regions. Then, a uniform metal layer is formed on the source/drain regions 101 by means of metal sputtering or Chemical Vapor Deposition. Preferably, the metal can be Ni; of course, it also can be other metal as deem appropriate, for example, Ti, Co, or Cu. Then, the semiconductor structure is annealed; other annealing processes, such as rapid thermal annealing and spike annealing, may be implemented in other embodiments. According to embodiments of the present invention, a device is usually annealed through transient annealing, for example, laser annealing at a temperature above 1000° C. for a period of microseconds, so as to enable the deposited metal to react with the amorphous compound formed within the source/drain regions 101 to form a metal silicide 122. Finally, the deposited metal that remains from the reaction may be removed through chemical etching The amorphous compound may be any one of amorphous silicon, amorphous SiGe, and amorphous SiC. The benefit of forming the metal silicide 122 is to lower resistivity between the contact metal inside the contact vias 122 and source/drain regions 101, so as to further reduce the contact resistance.

It should be noted that the step of forming the metal silicide 122 as shown in FIG. 7 is a preferred step. Namely, it is also applicable to fill the through holes 120 directly with a contact metal so as to form contact vias 121, instead of forming the metal silicide 122.

As shown in FIG. 8, the contact vias 121 are formed through filling the through holes 120 with the contact metal by means of deposition. The contact metal has a lower portion that is electrically connected with the exposed source/drain regions 101 within the substrate 100 (the term “electrically connected” indicates that the lower portion of the contact metal may be in direct contact with the exposed source/drain regions 101 within the substrate 100, or in essence may be electrically connected with the exposed source/drain regions 101 within the substrate through the metal silicide 122 formed on the exposed source/drain regions 101 within the substrate 100). The contact metal extends through the first interlayer dielectric layer 115 via the through holes 120 and exposes its top surface.

Preferably, the material for the contact metal is W. Of course, the material for the contact metal include but not limited to one of W, Al, and TiAl alloy, or any combination thereof, according to the needs of manufacturing a semiconductor in practice. Optionally, prior to filling the contact metal, a lining layer (not shown) may be selectively formed on the interior sidewalls and the bottoms of the through holes 120. The lining layer may be formed on the interior sidewalls and the bottoms of the through holes 120 by means of such deposition processes as ALD, CVD, and PVD. The material for the lining layer can be Ti, TiN, Ta, TaN, Ru, or their combinations; the thickness of the lining layer may be between 5 nm and 20 nm, for example, nm or 15 nm.

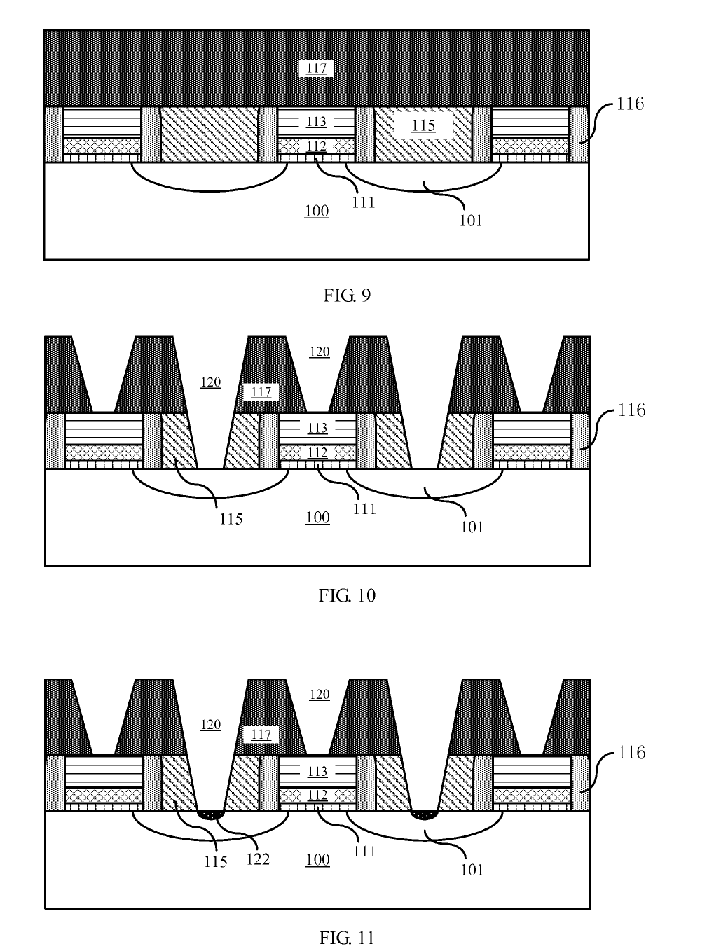

FIGS. 9-12 illustrate cross-sectional structural diagrams of contact vias of another type at respective stages of manufacturing in conjunction with the present invention.

With reference to FIG. 9, a second interlayer dielectric layer 117 is formed to cover the gate stack and the first interlayer dielectric layer 115. The second interlayer dielectric layer 117 may be formed by means of Chemical Vapor Deposition (CVD), High-density Plasma CVD, spin coating, or other method as appropriate. The material for the second interlayer dielectric layer 117 may include SiO₂, carbon-doped SiO₂, BPSG, PSG, UGS, Si₂N₂O, a low-k material, or their combinations. Preferably, the second interlayer dielectric layer 117 is made from the same material as that for the first interlayer dielectric layer 115, in order to simplify the etching process at formation of through holes 120.

As shown in FIG. 10, the second interlayer dielectric layer 117 and the first interlayer dielectric layer 115 are etched to form through holes 120, from which the source/drain regions 101 and the gate stack on the substrate 100 are at least partially exposed. Specifically, the through holes 120 may be formed through etching the first interlayer dielectric layer 115 and the second interlayer dielectric layer 117 by means of dry etching, wet etching or other etching method as appropriate. After formation of through holes 120, the source/drain regions 101 within the substrate 100 are exposed, and the upper surface of the gate stack is partially exposed. In case the source/drain regions 101 are raised source/drain structures formed by means of selective epitaxial growth, and the top surfaces of the epitaxial portions are higher than the bottom of the gate stack, then the through holes 120 may be formed as deep as reaching locations inside the source/drain regions 101 that are at the same level as the bottom of the gate stack. In this way, when the contact vias 121 are formed through filling the through holes 120 with a contact metal, the contact metal may be in contact with the source/drain regions 101 at the bottom and portions of the sidewalls of the through holes 120, which therefore further increases the contact area yet reduces the contact resistance.

As shown in FIG. 11, the exposed source/drain regions 101 are located at bottoms of the through holes 120. A metal is deposited on the source/drain regions 101 and then annealed to form metal silicide 122. Specifically, a pre-amorphization treatment is performed to the exposed source/drain regions 101 by way of implanting ions, depositing an amorphous compound, or selective growing from the through holes 120, so as to form partial amorphous silicon regions. Then, a uniform metal layer is formed on the source/drain regions 101 by means of metal sputtering or Chemical Vapor Deposition. Preferably, the metal can be Ni; of course, it also can be other metal as deem appropriate, for example, Ti, Co, or Cu. Then, the semiconductor structure is annealed; other annealing processes, such as rapid thermal annealing and spike annealing, may be applied in other embodiments. According to embodiments of the present invention, a device is usually annealed through transient annealing, for example, laser annealing at a temperature above 1000° C. for a period of microseconds, so as to enable the deposited metal to react with the amorphous compound formed within the source/drain regions 101 to form metal silicide 122. Finally, the deposited metal that remains from the reaction may be removed through chemical etching. The amorphous compound could be anyone of the following: amorphous silicon, amorphous SiGe, and amorphous SiC. The benefit of forming the metal silicide 122 is to lower resistivity between the contact metal inside the contact vias 122 and the source/drain regions 101 to further reduce the contact resistance.

It should be noted that the step of forming the metal silicide 122 shown in FIG. 7 is a preferred step; namely, it is also applicable to directly fill the through holes 120 with a contact metal so as to form contact vias 121, instead of forming the metal silicide 122.

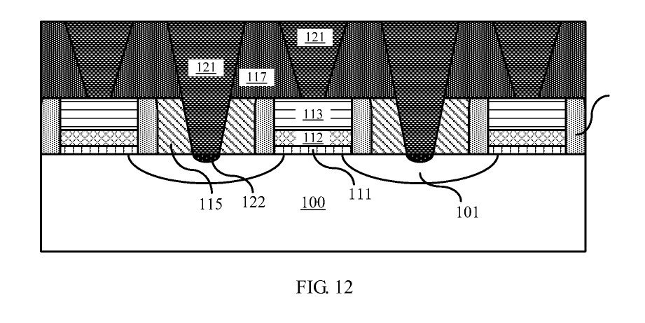

As shown in FIG. 12, the contact vias 121 are formed through filling the through holes 120 with the contact metal by means of deposition. The contact metal extends through the second interlayer dielectric layer 117 and the first interlayer dielectric layer 115 via the through hole 120, and exposes the top surfaces thereof from the second interlayer dielectric layer 117.

Preferably, the material for the contact metal is W. Of course, the material for the contact metal includes but not limited to one of W, Al, and TiAl alloy, or any combination thereof, according to the needs of manufacturing a semiconductor in practice.

As stated above, since the difference of heights between the gate and the source/drain is reduced, thus the distance to be etched at the time of etching through holes is reduced accordingly. Therefore, as compared to the traditional process of etching through holes, both the etching distance and etching accuracy become easier to control, which thus further optimizes the process for etching through holes.

Owing to implementation of the method for manufacturing a semiconductor structure provided by the present invention, the gate height is effectively shortened, and such a decrease in the gate height causes no unfavorable effect to the performance of a semiconductor device.

Although the exemplary embodiments and their advantages have been described in detail, it should be understood that various alternations, substitutions, and modifications may be made to the embodiments without departing from the spirit of the present invention and the scope as defined by the appended claims. As to other examples, it may be easily recognized by a person of ordinary skill in the art that the order of the process steps may be changed without departing from the scope of the present invention.

In addition, the scope to which the present invention is applied is not limited to the process, mechanism, manufacture, material composition, means, methods, and steps described in the specific embodiments in the specification. According to the disclosure of the present invention, a person of ordinary skill in the art would readily appreciate the disclosure of the present invention that the process, mechanism, manufacture, material composition, means, methods, and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods, or steps.

1. A method for manufacturing a semiconductor structure, comprising:
(a) providing a semiconductor substrate, and sequentially forming a gate dielectric layer, a metal gate, a CMP stop layer and a poly silicon layer on the semiconductor substrate;
(b) etching the gate dielectric layer, the metal gate, the CMP stop layer, and the poly silicon layer to form a gate stack;
(c) forming a first interlayer dielectric layer on the semiconductor substrate to cover the gate stack on the semiconductor substrate; and
(d) performing a planarization process such that the CMP stop layer is exposed and flushed with the upper surface of the first interlayer dielectric layer.

2. The method as defined in claim 1, wherein the hardness coefficient of the CMP stop layer is greater than the hardness coefficient of the poly silicon layer.

3. The method as defined in claim 1, wherein the material for the CMP stop layer includes one of Ni, Ti, Cr, Pt and TiN, or any combination thereof.

4. The method as defined in claim 1, wherein the total thickness of the metal gate and the CMP stop layer is about 20 nm.

5. The method as defined in claim 1, wherein the thickness of the metal gate is about 5 nm, and the thickness of the CMP stop layer is about 15 nm.

6. The method as defined in claim 1, wherein after step (b), the method further comprises: forming source/drain regions on both sides of the gate stack.

7. The method as defined in claim 6, wherein after step (d), the method further comprises: forming contact vias.

8. The method as defined in claim 7, wherein forming contact vias further comprises:
(f) forming through holes in the first interlayer dielectric layer to at least partially expose the source/drain regions in the substrate;
(g) forming metal silicide on the exposed source/drain regions within the substrate; and
(h) filling the through holes with a contact metal.

9. The method as defined in claim 7, wherein forming contact vias further comprises:
(i) forming a second interlayer dielectric layer to cover the gate stack and the first interlayer dielectric layer;
(j) etching the second interlayer dielectric layer and the first interlayer dielectric layer to form through holes, so as to at least partially expose the source/drain regions and the gate stack on the substrate; and
(k) filling the through holes with a contact metal.

10. A semiconductor structure comprising a substrate, a gate stack, a first interlayer dielectric layer and source/drain regions, wherein:
the source/drain regions are embedded within the substrate, the gate stack is formed on the substrate, and the first interlayer dielectric layer covers the source/drain regions, and wherein:
the gate stack sequentially comprises: a gate dielectric layer in contact with the substrate, a metal gate and a CMP stop layer.

11. The semiconductor structure as defined in claim 8, wherein the hardness coefficient of the CMP stop layer is greater than the hardness coefficient of poly silicon.

12. The semiconductor structure as defined in claim 8, wherein the total thickness of the metal gate and the CMP stop layer is about 20 nm.

13. The semiconductor structure as defined in claim 8, wherein the thickness of the metal gate is about 5 nm, and the thickness of the CMP stop layer is about 15 nm.

14. The semiconductor structure as defined in claim 8, wherein the material for the CMP stop layer includes one of Ni, Ti, Cr, Pt and TiN, or any combination thereof.

15. The semiconductor structure of claim 8, wherein the semiconductor structure further comprises contact vias.
